(19) United States
(12) Patent Application Publication
(10) Pub. No.: US 2007/0281403 A1
(43) Pub. Date: Dec. 6, 2007

(54) Method of enhancing gate lithography performance by polysilicon chemical-mechanical polishing

(76) Inventors: Mon-Chin Tsai, Shanghai (CN); Been-Jon Woo, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 11/444,323

(22) Filed: Jun. 1, 2006

(51) Int. Cl. H01L 21/84; H01L 21/302

(52) U.S. Cl. 438/153; 438/691; 257/E21.23

(57) ABSTRACT

A method of enhancing gate lithography performance by polysilicon chemical-mechanical polishing includes depositing a gate polysilicon layer on a semiconductor substrate which has a field oxide isolation structure, and then performing a polysilicon chemical-mechanical polishing after a gate polysilicon layer is deposited in order to smooth the uneven polysilicon surface resulting from the field oxide isolation structure so as to lessen the next lithography process fault because of the non-flatness.

### BACKGROUND OF THE INVENTION

1. Field of the Invention

The present invention relates to chemical-mechanical polishing, and more particularly to a method of enhancing gate lithography performance by polysilicon chemical-mechanical polishing, which performs a chemical-mechanical polishing process over a gate polysilicon layer of a semiconductor substrate which has a field oxide isolation structure to obtain gate polysilicon layers with the best planarization surface.

2. Description of the Prior Art

The modern semiconductor manufacturing needs to pack hundreds of thousands of transistors or even millions of transistors over a silicon surface area of 1˜3 cm². So as to avoid the operating disturbance between the transistors, it is essential to try to make every transistor on integrated circuits isolated from others in case of short circuit.

In the world, most adapt a local oxidation of silicon (LOCOS) to isolate MOS transistors. But because of stepping into a deep submicron era, high-density distribution of transistors will make it obvious that the field oxide (FOX) manufactured by LOCOS makes the surface of gate polysilicon deposited subsequently rough and uneven. Thus, the collimating ability of the next gate lithography process becomes worse relatively.

Consequently, the present invention proposes a method of enhancing gate lithography performance by polysilicon chemical-mechanical polishing (CMP), which overcomes the defect of the uneven polysilicon surface and makes a semiconductor substrate that has a field oxide structure suitable for much denser distribution of transistors in the deep submicron era.

### SUMMARY OF THE INVENTION

An object of the present invention is to provide a method of enhancing gate lithography performance by polysilicon chemical-mechanical polishing, which makes the uneven polysilicon surface resulting from a field oxide isolation structure is at the least degree level.

Another objective of the present invention is to provide a method of enhancing gate lithography performance by polysilicon chemical-mechanical polishing, which improves gate lithography performance of a semiconductor substrate that has a field oxide isolation structure.

Further another objective of the present invention is to provide a method of enhancing gate lithography performance by polysilicon chemical-mechanical polishing, which is suitable for semiconductor substrates that have denser and denser distribution of transistors.

To achieve the abovementioned objectives, the present invention presents a method of enhancing gate lithography performance by polysilicon chemical polishing. The invention first provides a semiconductor substrate that already has a field oxide isolation structure, and then forms a gate oxide layer and a polysilicon layer in turn on the semiconductor substrate, and at last performs a chemical-mechanical polishing process over the polysilicon layer to get the better performance of gate lithography.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1-6 are cross-sectional structure views of each step according to an embodiment of the present invention.

### DESCRIPTION OF THE PREFERRED EMBODIMENTS

The present invention presents a method of enhancing gate lithography performance by polysilicon chemical-mechanical polishing, which treats a semiconductor substrate having a field oxide isolation structure after a polysilicon deposition process by polysilicon chemical-mechanical polishing (CMP) to smooth the uneven polysilicon surface resulting from the field oxide isolation structure so as to avoid shortcomings of the poor lithography performance.

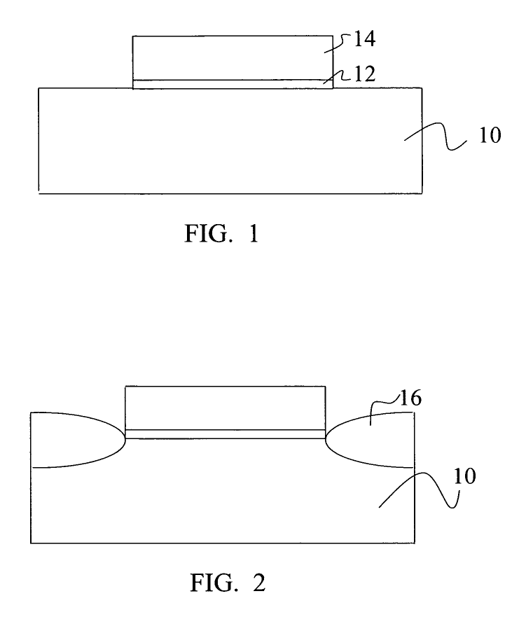

FIGS. 1-6 are diagrams schematically showing each step of a preferred embodiment of the present invention, wherein the focus of the present invention depicts in detail that after a field oxide isolation structure process, the deposited polysilicon is treated by CMP and a most common manufacturing method used to form the gate is just to describe this invention but not to limit the applications of this invention.

Referring to FIG. 1, a semiconductor substrate 10 is provided, a pad oxide layer 12 serving as a buffer layer is deposited on semiconductor substrate 10 by means of thermal oxidation, a pad silicon nitride layer 14 serving as an oxide barrier layer is deposited on pad oxide layer 12 by means of low-pressure chemical vapor deposition (LPVCD), and a first patterning photoresist is formed on pad silicon nitride layer 14. Then, an active region is defined by the patterning photoresist to lithograph semiconductor substrate 10 and then the first patterning photoresist is removed, as shown in FIG. 1.

Then, referring to FIG. 2, semiconductor substrate 10 is performed by local oxidation of silicon (LOCOS) to form a field oxide isolation structure 16. Field oxide isolation structure 16 is manufactured in an oxidation furnace, and at this time, oxidizing Si into SiO₂ will increase volume and make the surface of semiconductor substrate 10 rough.

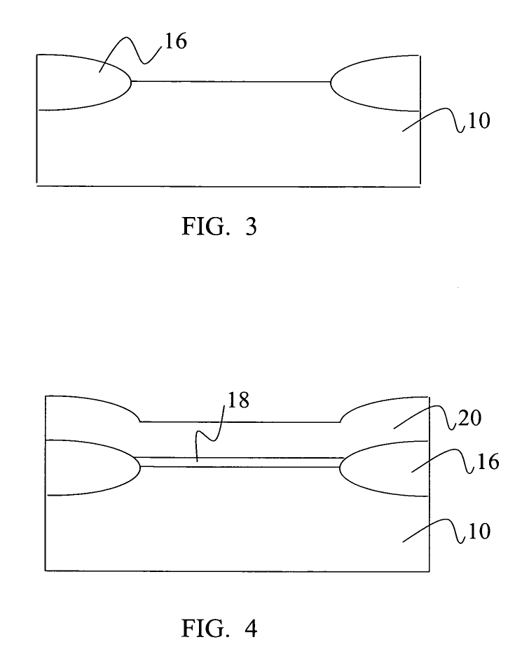

Then, as shown in FIG. 3, pad silicon nitride layer 14 is removed by using thermal H₃PO₄ wet etching, and semiconductor substrate 10 is put into a HF chemical bath to remove oxide layer 12, and then semiconductor substrate 10 is cleaned to grow again the better quality of SiO₂ film to serve as a gate oxide layer.

As shown in FIG. 4, high quality of a gate oxide layer 18 is formed on the surface of semiconductor substrate 10 by using thermal oxidation and a polysilicon layer 20 is deposited on gate oxide layer 18 by using low-pressure chemical vapor deposition (LPVCD), and polysilicon layer 20 covers the entire surface of gate oxide layer 18 and field oxide isolation structure 16.

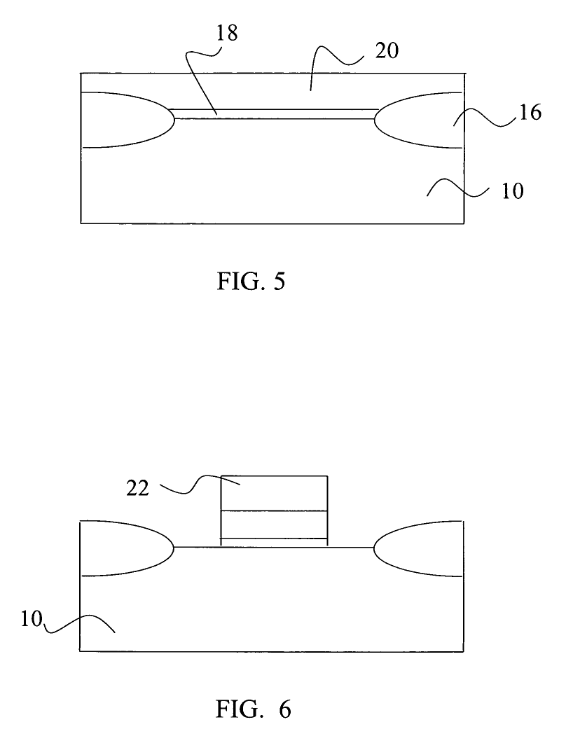

Furthermore, referring to FIG. 5, use chemical-mechanical polishing (CMP) to planarize and smooth the surface of polysilicon layer 20 which covers the surface of gate oxide layer 18 and field oxide isolation structure 16, as shown in FIG. 5.

Then, as shown in FIG. 6, metal layers 22 are deposited on polysilicon layer 20 and a second patterning photoresist is formed on metal layers 22. Finally, semiconductor substrate 10 is under the lithography process by using the second patterning photoresist, and then the second patterning photoresist is removed.

In summary, the present invention is a CMP process, which can avoid decreasing the lithography performance resulting from the uneven polysilicon surface, and make the conventional field oxide local structure suitable for a tendency towards increasing the transistor density per unit area.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

What is claimed is:

1. A method of enhancing gate lithography performance by polysilicon chemical-mechanical polishing, comprising the steps of:
providing a semiconductor substrate which has a field oxide isolation structure formed thereon;
forming a gate oxide layer and a polysilicon layer in turn on the semiconductor substrate; and
performing a chemical-mechanical polishing process over the polysilicon layer.

2. The method of improving gate lithography performance by polysilicon chemical-mechanical polishing according to claim 1, wherein the step of forming the field oxide isolation structure comprising:
forming a component isolation mask on the semiconductor substrate;
performing a field oxide isolation structure process over the semiconductor substrate; and
removing the component isolation mask.

3. The method of improving gate lithography performance by polysilicon chemical-mechanical polishing according to claim 2, wherein the component isolation mask includes a pad silicon oxide layer and a pad silicon nitride layer located on the pad silicon oxide layer.

4. The method of improving gate lithography performance by polysilicon chemical-mechanical polishing according to claim 3, wherein the pad silicon oxide layer is formed by thermal oxidation.

5. The method of improving gate lithography performance by polysilicon chemical-mechanical polishing according to claim 3, wherein the pad silicon nitride layer is made by low-pressure chemical vapor deposition.

6. The method of improving gate lithography performance by polysilicon chemical-mechanical polishing according to claim 3, wherein the pad silicon nitride layer is removed by thermal H₃PO₄ wet etching.

7. The method of improving gate lithography performance by polysilicon chemical-mechanical polishing according to claim 3, wherein the pad silicon oxide layer is removed by using HF liquid.

8. The method of improving gate lithography performance by polysilicon chemical-mechanical polishing according to claim 1, wherein the gate oxide layer is made bythermal oxidation.

9. The method of improving gate lithography performance by polysilicon chemical-mechanical polishing according to claim 1, wherein the polysilicon layer is deposited by low-pressure chemical vapor deposition.

10. The method of improving gate lithography performance by polysilicon chemical-mechanical polishing according to claim 1, wherein after completing the polysilicon chemical-mechanical polishing process, a gate is formed on the semiconductor substrate.
